(19) United States
(12) Patent Application Publication
(10) Pub. No.: US 2026/0293033 A1
(43) Pub. Date: Sep. 24, 2026

(54) AUXILIARY SLIDING CONNECTION ASSEMBLY

(71) Applicant: KANG YANG HARDWARE ENTERPRISES CO., LTD., New Taipei City (TW)

(72) Inventor: Shu-Li HSIEH, New Taipei City (TW)

(21) Appl. No.: 19/197,043

(22) Filed: May 2, 2025

(30) Foreign Application Priority Data
Mar. 20, 2025 (TW) 114110593

(51) Int. Cl. H05K 7/14

(52) U.S. Cl. CPC H05K 7/1489

(57) ABSTRACT

An auxiliary sliding connection assembly includes: a sliding rail device having a first fixing rail and a second fixing rail respectively and axially formed with a pair of rail slots at a lateral side thereof, the first fixing rail including a positioning tower having an accommodation slot provided with a first bolt hole communicating with a rail slot and a hinge connecting member; and a locking member including a lock body having a first locking bolt radially protruding out of the first bolt hole, the lock body has a positioning device having a swing member, the swing member has at least one guide tenon; and the lock body has at least one rail mechanism having a height differentiation and formed in a two-staged positioning status and located at a position corresponding to a lateral wall of the at least one guide tenon.

### BACKGROUND OF THE INVENTION

### Field of the Invention

The present invention relates to an auxiliary sliding connection assembly, especially to an auxiliary sliding connection assembly allowing an electronic device, for example a network card to slide, to be connected and locked.

### Description of the Related Art

A sliding rail structure is commonly applied for allowing two electronic devices to be inserted or removed, so that an electrical connection can be established or terminated, and the above-mentioned technical means is a well-known art by the skilled people.

Please refer to FIG. 1, which is a perspective exploded view illustrating a conventional removable electronic device according to a first embodiment. The removable electronic device includes a main frame 10, for example a server, and a removable unit 20, for example a network card. The main frame 10 has a first board member 101, for example a mother board, having a connector 102, and two sides of the connector 102 are oppositely disposed with a pair of fixing rails 103, and each of the fixing rails 103 has a rail slot 104. The removable unit 20 has a second board member 201, for example a circuit board (as shown in FIG. 2), an inner side of the second board member 201 is disposed with a connecting plug (not shown in figures due to the projection angle) at a location corresponding to the connector 102, and two sides thereof are inwardly and oppositely protruded with a pair of sliding rails 202, and each of the sliding rails 202 has a locking hole 203.

When the removable unit 20 is desired to be combined in the main frame 10, the pair of sliding rails 202 are inserted by a user in the pair of rail slots 104 of the pair of fixing rails 103 and inwardly slide along the pair of rail slots 104 till the connecting plug is inserted in the connector 102, thereby forming an electric connection.

Please refer to FIG. 2, which discloses an arranging means of the first board member 101 and the second board member 201, in other words the pair of fixing rails 103 are oppositely arranged with an interval on a top surface of the first board member 101, and the second board member 201 is inserted between the pair of fixing rails 103, and located above the first board member 101, so that the second board member 102 is formed in an on-board status relative to the first board member 101.

Please refer to FIG. 3, which is a perspective exploded view illustrating a conventional removable electronic device according to a second embodiment. The removable electronic device includes a main frame 10, for example a server, and a removable unit 20, for example a network card. The main frame 10 has a first board member 101, for example a mother board, the first board member 101 has a rectangular board hole 105, and a connector 102 is disposed at an inner side of the board hole 105, and two sides of the board hole 105 are oppositely disposed with a pair of fixing rails 103, and each of the fixing rails 103 has a rail slot 104. The removable unit 20 has a second board member 201, for example a circuit board (as shown in FIG. 4), an inner side of the second board member 201 is disposed with a connecting plug (not shown in figures due to the projection angle) at a location corresponding to the connector 102, and two sides thereof are inwardly and oppositely protruded with a pair of sliding rails 202, and each of the sliding rails 202 has a locking hole 203.

When the removable unit 20 is desired to be combined in the main frame 10, the pair of sliding rails 202 are inserted by a user in the pair of rail slots 104 of the pair of fixing rails 103 and inwardly slide along the pair of rail slots 104 till the connecting plug is inserted in the connector 102, thereby forming an electric connection.

Please refer to FIG. 4, which discloses an arranging means of the first board member 101 and the second board member 201, in other words the pair of fixing rails 103 are oppositely arranged with an interval at two sides of the board hole 105, and the second board member 201 is inserted in the board hole 105 between the pair of fixing rails 103, so that the second board member 201 is formed in an in-board status relative to the first board member 101.

However, the pair of fixing rails 103 disclosed in the two embodiments are not provided with a locking and a positioning function, thus the main frame 10 and the removable unit 20 are connected and fastened only via a holding and clamping force generated between the connector 102 and the connecting plug. When the main frame 10 is in a vibrating environment, the connection between the connector 102 and the connecting plug may be loosened, and the electrical connection is no longer provided; accordingly, the above-mentioned disadvantage shall be improved by the skilled people in the art.

### SUMMARY OF THE INVENTION

One primary objective of the present invention is to provide an auxiliary sliding connection assembly, which includes a pair of fixing rails capable of being combined with a first board member in an on-board status or an in-board status, and the at least one fixing rail is disposed with a locking mechanism, capable of manually locking and unlocking a locking hole, arranged at a location corresponding to the locking hole preformed on a second board member, so that a removeable unit, for example a network card, having the second board member, for example a circuit board, is able to generate a locking and positioning function to a main frame, for example a server, having the first board member, for example a motherboard, during a sliding process of the pair of fixing rails, thus the removable unit is prevented from loosening or separating from the main frame, thereby ensuring the stability of an electric connection.

For achieving said objective, one technical solution provided by the present invention is to provide an auxiliary sliding connection assembly, which includes a sliding rail device, the sliding rail device includes a first fixing rail and a second fixing rail arranged with an interval and disposed on a first board member, a lateral surface of the first fixing rail and that of the second fixing rail, which are opposite to each other, are axially formed with a pair of rail slots respectively for allowing a pair of sliding rails at two sides of a second board member to be disposed and slide thereon; wherein the first fixing rail has a positioning tower allowing a locking member to be disposed thereon, and being arranged at a location corresponding to a locking hole formed on the pair of sliding rails, the positioning tower has an accommodation slot, the accommodation slot has an opening and a first bolt hole oppositely located at a top end and a bottom end thereof, and the first bolt hole is in communication with one of the rail slots, the positioning tower further has a hinge connecting member disposed at a bottom end thereof; and a locking member having a lock body extended with a first locking bolt at a bottom end thereof, the first locking bolt is able to radially protrude out of the first bolt hole, an elastic retracting mechanism is disposed at a bottom end of an adjacently connected surface defined by the lock body and the positioning tower, a position limiting mechanism is oppositely disposed on at least one lateral wall of the positioning tower and a lateral wall corresponding to the lock body, and the lock body has a positioning device at a location corresponding to the hinge connecting member, the positioning device includes a swing member pivotally connected to the hinge connecting member, at least one guide tenon is inwardly protruded on a top surface of the swing member; and the lock body has at least one rail mechanism having a height differentiation and formed in a two-staged positioning status and located at a position corresponding to a lateral wall of the at least one guide tenon; when the locking member is pressed, the elastic retracting mechanism is compressed to store energy, the position limiting mechanism determines a radial moving limitation in which the locking member moves in the positioning tower; and the at least one guide tenon moves within a preset stroke on the corresponding rail mechanism, so that the first locking bolt protrudes out of the first bolt hole and passes the locking hole in one of the rail slots, thereby forming a locking status; or the first locking bolt is released from the locking hole in one of the rail slots and retracted in the first bolt hole, thereby forming an unlocking status.

According to one embodiment of the present invention, a lateral piece is radially formed at a bottom end defined at another lateral surface of the first fixing rail and that of the second fixing rail, the lateral piece has at least one screw hole; wherein each of the screw holes is allowed to pass a so as to be screwed and connected to a penetrated hole correspondingly formed on the first board member.

According to one embodiment of the present invention, the at least one screw hole is selectively disposed in a plurality of protruding parts radially protruded from the lateral piece, respectively.

According to one embodiment of the present invention, the auxiliary sliding connection assembly further includes a guide mechanism, the guide mechanism is oppositely disposed with at least one guide rail at the at least one lateral wall of the positioning tower and the lateral wall corresponding to the lock body, and a guide slot sleeved in each of the guide rails, so that the locking member is able to radially move in the positioning tower in a stable and smooth manner.

For achieving said objective, another technical solution provided by the present invention is to provide an auxiliary sliding connection assembly, which includes a sliding rail device, the sliding rail device includes a first fixing rail disposed at a central segment of a first board member and a pair of second fixing rails arranged with an interval and disposed at two sides of the first fixing rail, two lateral surfaces of the first fixing rail and one lateral surface of the pair of second fixing rails, which are opposite to each other, are axially formed with two pairs of rail slots, each of the two pairs of rail slots allows a pair of sliding rails at two sides of a second board member to be disposed and slide thereon; wherein the first fixing rail has a positioning tower allowing a locking member to be disposed thereon, and being arranged at a location corresponding to a locking hole formed on the pair of sliding rails, the positioning tower has an accommodation slot, the accommodation slot has an opening and a first bolt hole and a second bolt hole oppositely located at a top end and a bottom end thereof, and the first bolt hole and the second bolt hole are in communication with one of the corresponding rail slots, the positioning tower further has a hinge connecting member disposed at a bottom end thereof; and a locking member having a lock body extended with a first locking bolt and a second locking bolt respectively protruded from two lateral walls thereof, the first locking bolt is able to radially protrude out of the first bolt hole and the second locking bolt is able to radially protrude out of the second bolt hole; an elastic retracting mechanism is disposed at a bottom end of an adjacently connected surface defined by the lock body and the positioning tower, a position limiting mechanism is oppositely disposed on at least one lateral wall of the positioning tower and a lateral wall corresponding to the lock body, and the lock body has a positioning device at a location corresponding to the hinge connecting member, the positioning device includes a swing member pivotally connected to the hinge connecting member, at least one guide tenon is inwardly protruded on a top surface of the swing member; and the lock body has at least one rail mechanism having a height differentiation and formed in a two-staged positioning status and located at a position corresponding to a lateral wall of the at least one guide tenon; when the locking member is pressed, the elastic retracting mechanism is compressed to store energy, the position limiting mechanism determines a radial moving limitation in which the locking member moves in the positioning tower; and the at least one guide tenon moves within a preset stroke on the corresponding rail mechanism, so that the first locking bolt and the second locking bolt respectively protrude out of the corresponding first bolt hole and the corresponding second bolt hole and respectively pass the locking hole in one of the rail slots, thereby forming a locking status; or the first locking bolt and the second locking bolt are respectively released from the locking hole in one of the rail slots and retracted in the corresponding first bolt hole and the corresponding second bolt hole, thereby forming an unlocking status.

According to one embodiment of the present invention, at least one bottom connection hole arranged with an interval is formed on a bottom surface of the first fixing rail, a lateral piece is radially formed at a bottom end defined at another lateral surface, opposite to first fixing rail, of the second fixing rail, the lateral piece has at least one screw hole; wherein each of the screw holes is allowed to pass so as to be screwed and connected to a penetrated hole correspondingly formed on the first board member.

According to one embodiment of the present invention, the at least one screw hole is selectively disposed in a plurality of protruding parts radially protruded from the lateral piece, respectively.

According to one embodiment of the present invention, the auxiliary sliding connection assembly further includes a guide mechanism, the guide mechanism is respectively disposed with a first guide slot communicating with the first bolt hole and a second guide slot communicating with the second bolt hole and arranged at two lateral walls of the positioning tower; the at least one lateral wall of the positioning tower and the lateral wall corresponding to the lock body; wherein the first locking bolt is sleeved in the first guide slot so as to radially move in the first bolt hole, and the second locking bolt is sleeved in the second guide slot so as to radially move in the second bolt hole, so that the locking member is able to radially move in the positioning tower in a stable and smooth manner.

According to one embodiment of the present invention, the first locking bolt, the first guide slot and the first bolt hole are staggeringly arranged relative to the second locking bolt, the second guide slot and the second bolt hole.

According to one embodiment of the present invention, the first locking bolt, the first guide slot and the first bolt hole are symmetrically arranged relative to the second locking bolt, the second guide slot and the second bolt hole.

According to one embodiment of the present invention, at least one positioning tenon is respectively protruded from a bottom surface of the first fixing rail and a bottom surface of the second fixing rail.

According to one embodiment of the present invention, the position limiting mechanism has at least one position limiting slot oppositely disposed on the at least one lateral wall of the positioning tower and the lateral wall corresponding to the lock body, and a block tenon sleeved in each of the position limiting slots to determine a radial moving stroke in which the locking member moves in the positioning tower, and the locking member is prevented from being released from the opening of the positioning tower.

According to one embodiment of the present invention, each of the block tenons has a downwardly-sloped inclined guide surface to facilitate the block tenon to be sleeved in the corresponding position limiting slot.

According to one embodiment of the present invention, the elastic retracting mechanism includes a support rod radially protruded from a middle segment defined on a bottom surface of the positioning tower, a bottom surface of the lock body is disposed with an elastic member sleeving the support rod and arranged at a location corresponding to the support rod, and an accommodation hole accommodating the elastic member and the support rod.

According to one embodiment of the present invention, the hinge connecting member includes at least one fasten sheet, and a buckle slot allowing the swing sheet to be buckled and arranged on a bottom surface of the fasten sheet.

According to one embodiment of the present invention, the rail mechanism includes a linear slot radially arranged, a heart-shaped concave slot connected to a downstream end of the linear slot, and an arc-shaped slot connected to a downstream end of the heart-shaped concave slot and an upstream end of the linear slot, wherein a first height differentiation segment is formed at a connected location defined by the heart-shaped concave slot and the linear slot, a second height differentiation segment is formed at a connected location defined by the arc-shaped slot and the linear slot, thereby configuring the rail mechanism formed in a two-staged positioning status with a unidirectional stroke.

### BRIEF DESCRIPTION OF THE DRAWINGS

To make it easier for our examiner to understand the objective of the invention, its structure, innovative features, and performance, we use preferred embodiments together with the accompanying drawings for the detailed description of the invention.

FIG. 1 is a perspective exploded view illustrating a conventional removable electronic device according to a first embodiment;

FIG. 2 is a schematic view illustrating the second board member being formed with an on-board status relative to the first board member of FIG. 1;

FIG. 3 is a perspective exploded view illustrating a conventional removable electronic device according to a second embodiment;

FIG. 4 is a schematic view illustrating the second board member being formed with an in-board status relative to the first board member of FIG. 3;

FIG. 5a is a perspective view illustrating an auxiliary sliding connection assembly according to the first embodiment of the present invention;

FIG. 5b is another perspective view illustrating the auxiliary sliding connection assembly according to the first embodiment of the present invention;

FIG. 6a is a perspective exploded view illustrating a first fixing rail and a locking member of FIG. 5a according to the first embodiment of the present invention;

FIG. 6b is another perspective exploded view illustrating the first fixing rail and the locking member of FIG. 5a according to the first embodiment of the present invention;

FIG. 7 is a perspective view illustrating the locking member according to the present invention;

FIG. 8 is a schematic view illustrating the locking member on the first fixing rail of FIG. 5a not yet being operated;

FIG. 9 is a schematic view illustrating the locking member on the first fixing rail of FIG. 8 being pressed for forming a locking status;

FIG. 10 is a schematic view illustrating the locking member on the first fixing rail of FIG. 9 being continuously pressed for forming an unlocking status;

FIG. 11 is a schematic view illustrating the locking member on the first fixing rail of FIG. 10 being unlocked and automatically recovered;

FIG. 12 is a perspective exploded view illustrating the auxiliary sliding connection assembly of FIG. 5a and FIG. 5b being assembled with a main frame of a removable electronic device;

FIG. 13 is a perspective exploded view illustrating the main frame and the removeable unit of FIG. 12 before being processed with an inserting operation;

FIG. 14 is a perspective view illustrating the removeable unit of FIG. 13 being inserted in the main frame;

FIG. 15 is a partially enlarged cross sectional view of FIG. 14 taken along an A-A dashed line;

FIG. 16 is a perspective view illustrating the removeable unit of FIG. 14 being locked and fastened in the main frame;

FIG. 17 is a partially enlarged cross sectional view of FIG. 16 taken along a B-B dashed line;

FIG. 18 is a perspective view illustrating the auxiliary sliding connection assembly according to a second embodiment of the present invention;

FIG. 19a is a perspective exploded view illustrating a first fixing rail and a locking member of FIG. 18 according to the second embodiment of the present invention;

FIG. 19b is another perspective exploded view illustrating the first fixing rail and the locking member of FIG. 18 according to the second embodiment of the present invention;

FIG. 19c is another perspective exploded view illustrating the first fixing rail and the locking member of FIG. 18 according to the second embodiment of the present invention;

FIG. 19d is one another perspective exploded view illustrating the first fixing rail and the locking member of FIG. 18 according to the second embodiment of the present invention;

FIG. 20 is a perspective view illustrating the two removeable units of the removeable electronic device of FIG. 18 being locked and fastened in the main frame according to the present invention;

FIG. 21 is a perspective view illustrating the auxiliary sliding connection assembly according to a third embodiment of the present invention;

FIG. 22a is a perspective exploded view illustrating a first fixing rail and a locking member of FIG. 21 according to the third embodiment of the present invention;

FIG. 22b is another perspective exploded view illustrating the first fixing rail and the locking member of FIG. 21 according to the third embodiment of the present invention;

FIG. 22c is another perspective exploded view illustrating the first fixing rail and the locking member of FIG. 21 according to the third embodiment of the present invention;

FIG. 22d is one another perspective exploded view illustrating the first fixing rail and the locking member of FIG. 21 according to the third embodiment of the present invention; and

FIG. 23 is a perspective view illustrating the two removeable units of the removeable electronic device of FIG. 21 being locked and fastened in the main frame according to the present invention.

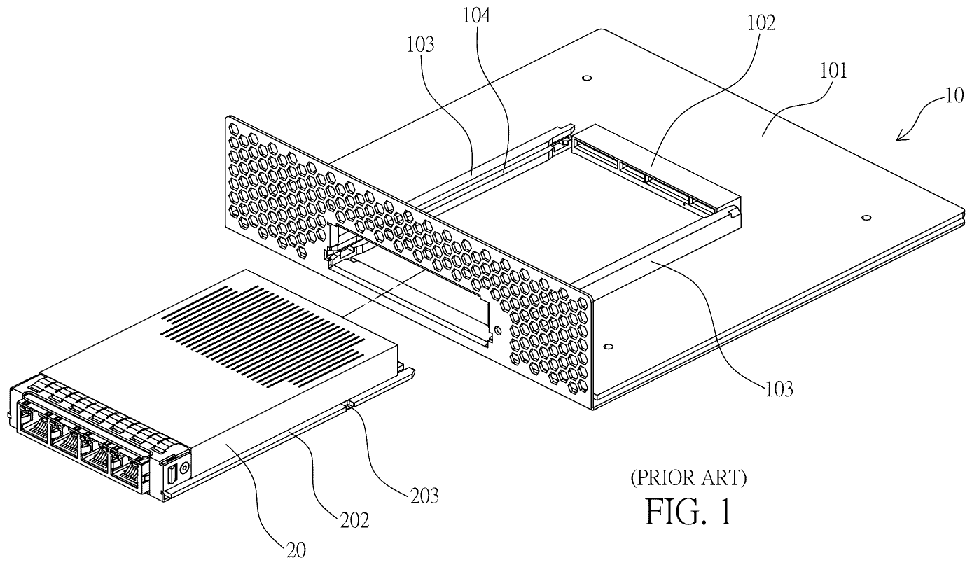

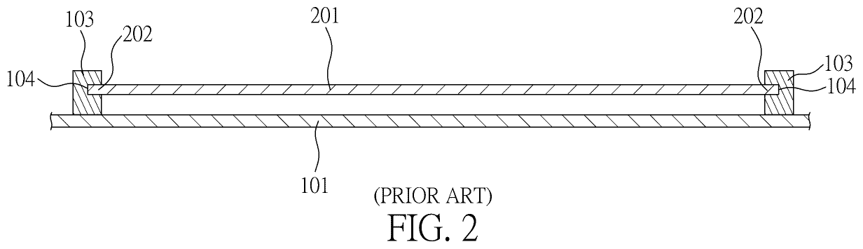

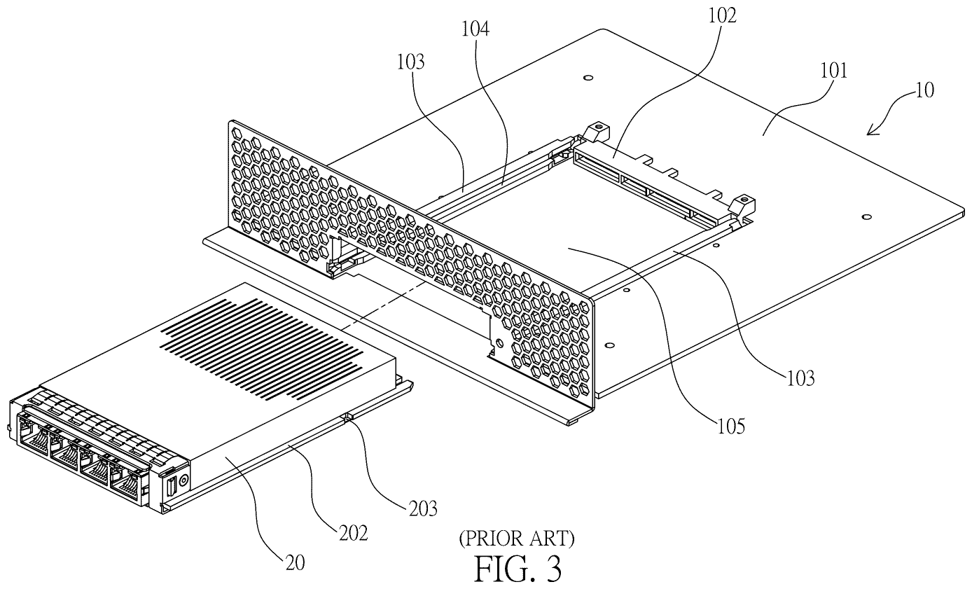

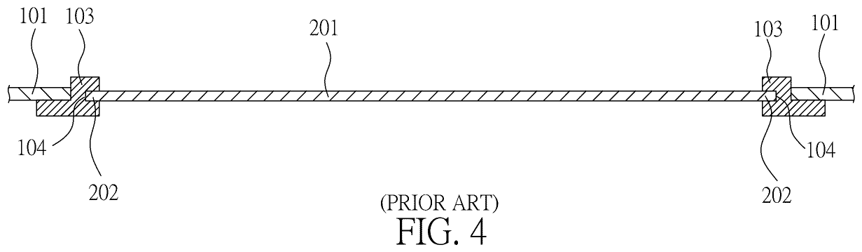

### DETAILED DESCRIPTION OF THE PREFERRED EMBODIMENTS

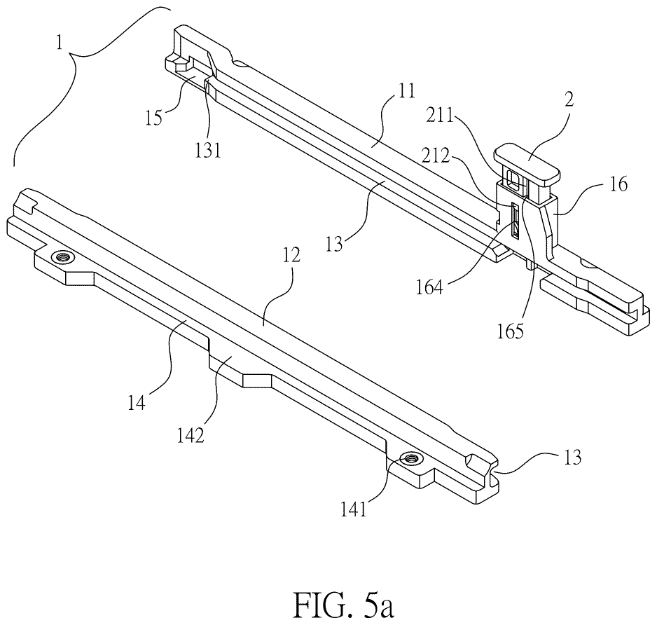

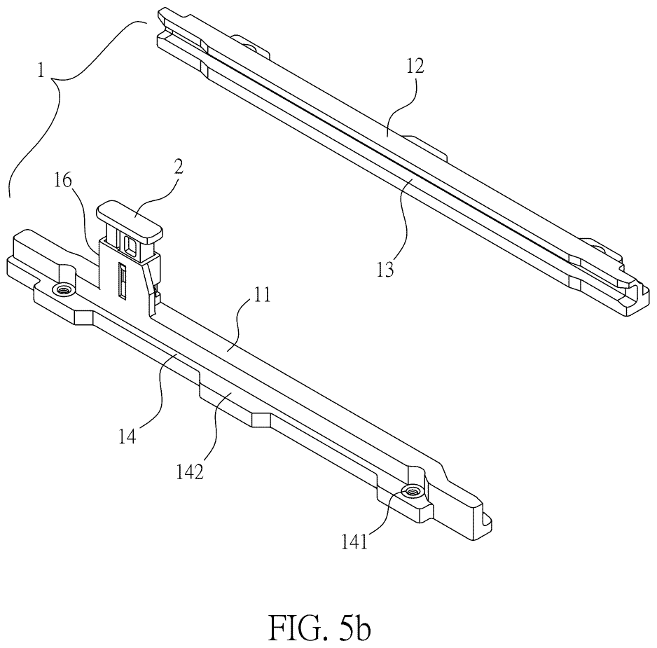

Please refer rrom FIG. 5a to FIG. 11 and according to a first embodiment of the present invention, an auxiliary sliding connection assembly is disclosed. The auxiliary sliding connection assembly is an insulation body integrally formed with a plastic material being processed with an injection molding means, and includes a sliding rail device 1 and a locking member 2.

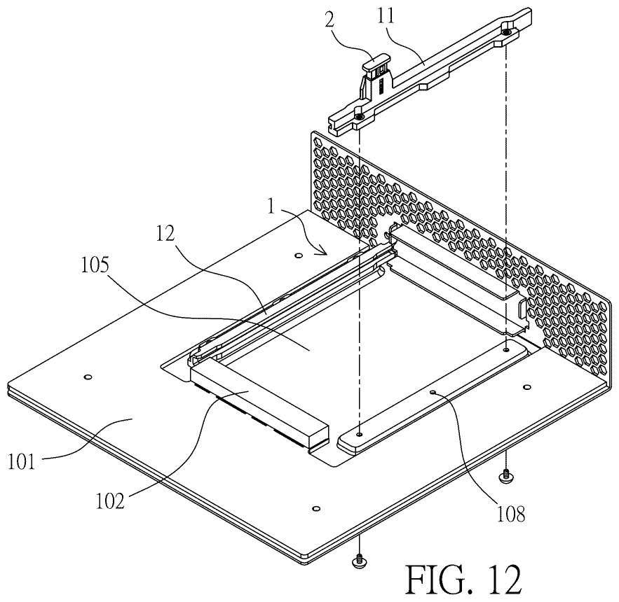

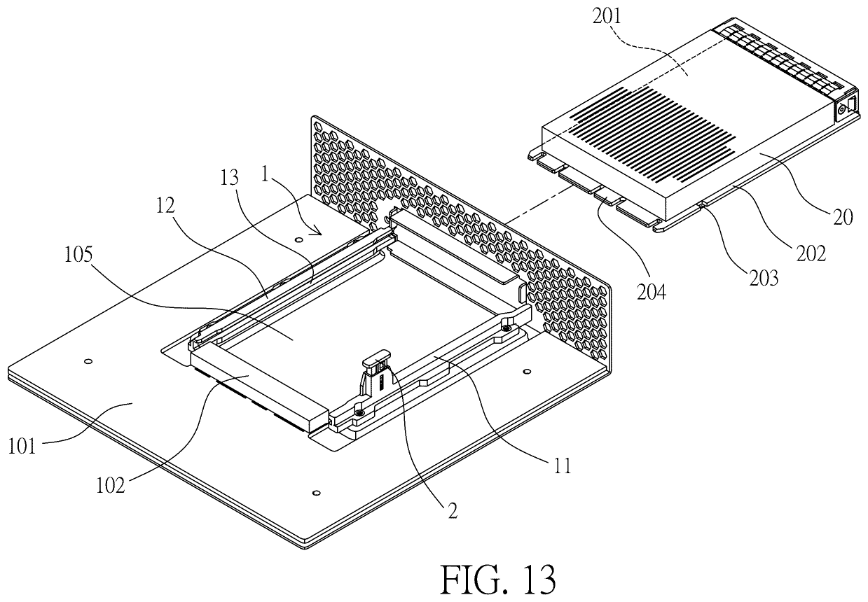

The sliding rail device 1 includes a first fixing rail 11 and a second fixing rail 12 arranged with an interval. A lateral surface of the first fixing rail 11 and that of the second fixing rail 12, which are opposite to each other, are axially formed with a rail slot 13 respectively. For providing a function of allowing a pair of sliding rails 202 (as shown in FIG. 13) of a removeable unit 20 to be easily inserted in the pair of rail slots 13, at least two wall surfaces defined at at least one end of the pair of rail slots 13 are formed with a guide opening 131 in a status of gradually shrunk towards the center. Moreover, a bottom surface of the first fixing rail 11 and that of the second fixing rail 12 (not shown in figures) are respectively formed with at least one positioning tenon 132 so as to be easily mounted in a positioning hole 108 (as shown in FIG. 12) correspondingly formed on a first board member 101 of a main frame 10.

A bottom end defined at another lateral surface of the first fixing rail 11 and that of the second fixing rail 12 are radially formed with a lateral piece 14. The installation of the lateral piece 14 is to allow the lateral piece 14 to be directly disposed on the first board member 101, for example a mother board, of the main frame 10 of a removable electronic device, thereby forming an on-board status; or the lateral piece 14 is abutted against an inner bottom surface of a rectangular sheet hole 105 (as shown in FIG. 12 and FIG. 13) preformed on the first board member 101 of the main frame 10, thereby forming the on-board status.

Please refer to FIG. 5a and FIG. 5b, the lateral piece 14 has at least one screw hole 141, each screw hole 141 allows a conventional screwing member, for example a screw, to pass so as to be screwed and connected to a penetrated hole preformed on the first board member 101. Wherein, the at least one screw hole 141 is selectively disposed in a plurality of protruding parts 142 radially protruded from the lateral piece 14, respectively. As shown in figures, there are two screw holes 141, which are disposed at a front portion and a rear portion of the protruding part 142, respectively.

Moreover, a head portion defined at a bottom end of the rail slot 13 is formed with a dodging slot 15, a main function of the dodging slot 15 is to allow a retracting board member (known as a conventional art and not provided with a code) of the removable unit 20 to be provided with a dodging space.

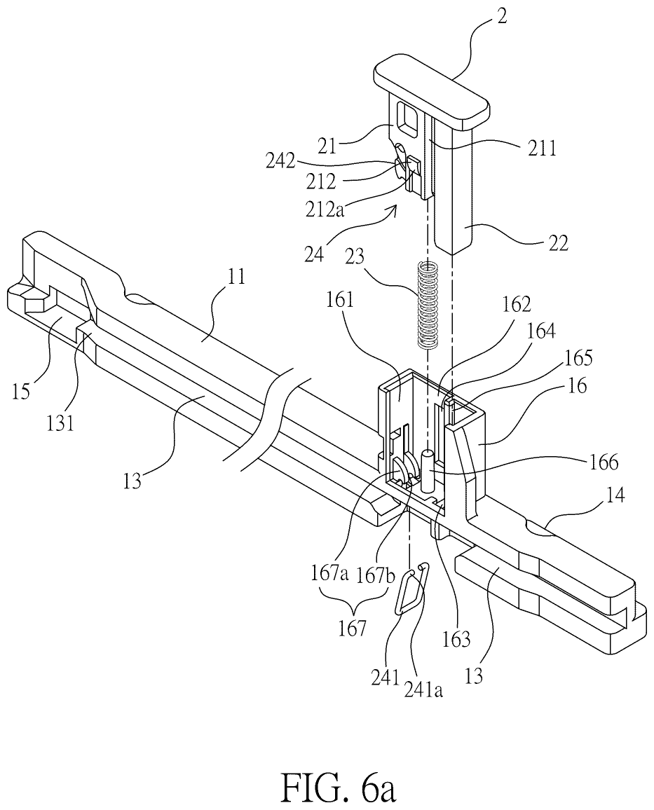

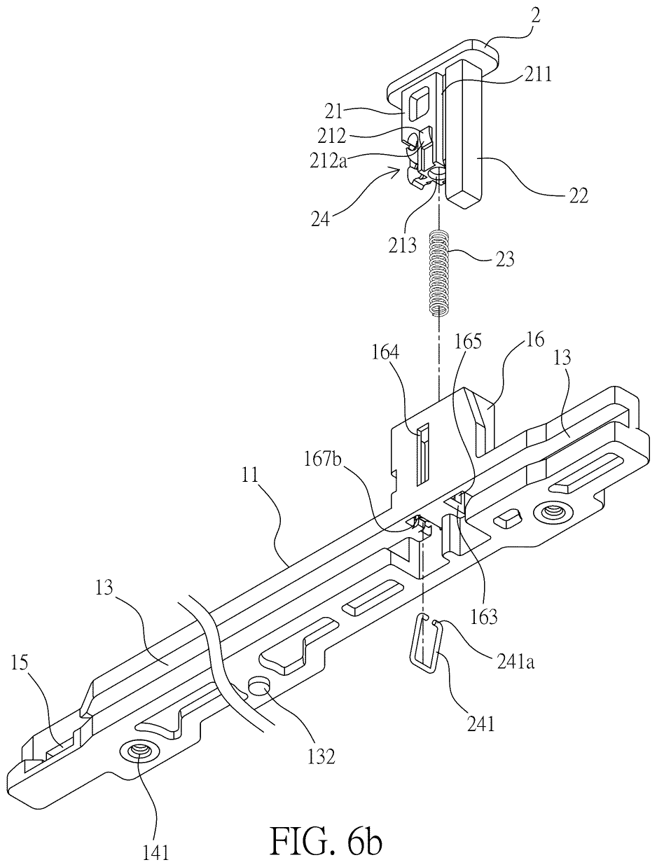

Furthermore, a top surface of the first fixing rail 11 has a positioning tower 16 allowing the locking member 2 to be disposed thereon, and being arranged at a location corresponding to a locking hole 203 formed on the pair of sliding rails 202 at a bottom end of the removable unit 20. The positioning tower 16 has an accommodation slot 161 (as shown in FIG. 6a, wherein an inner wall of the positioning tower 16 is deleted in FIG. 6a for providing clear illustrations). The accommodation slot 161 has an opening 162 and a first bolt hole 163 oppositely located at a top end and a bottom end thereof, and the first bolt hole 163 is in communication with the rail slot 13.

Moreover, at least one lateral wall of the positioning tower 16 is radially formed with at least one position limiting slot 164 of a position limiting mechanism and at least one guide rail 165 of a guide mechanism, an inner lateral wall and an outer lateral wall of the positioning tower 16 are respectively formed with the position limiting slot 164 and the guide rail 165 as shown in FIG. 6a and FIG. 6b. The position limiting slots 164 are used to be combined with the locking member 2, determine a radial moving stroke in which the locking member 2 moves in the positioning tower 16, meanwhile the locking member 2 is prevented from being released from the opening 162 of the positioning tower 16. The guide rails 165 allow the locking member 2 to radially move in the positioning tower 16 in a stable and smooth manner.

Moreover, a middle segment defined at a bottom end of the positioning tower 16 is radially protruded with a support rod 166 of an elastic retracting mechanism, and a corner thereof is disposed with a hinge connecting member 167. The hinge connecting member 167 includes at least one fasten sheet 167a and a buckle slot 167b located on a bottom surface of the fasten sheet 167a.

The locking member 2 includes a lock body 21, and a bottom end defined at one side thereof is extended with a first locking bolt 22. The first locking bolt 22 is disposed in via the opening 162 and protrudes out of the first bolt hole 163 with a radially moving means. A guide slot 211 of the guide mechanism is radially formed between the first locking bolt 22 and the lock body 21 at a location corresponding to each of the guide rails 165, and a block tenon 212 of the position limiting mechanism is formed on at least one lateral wall of the lock body 21 at a location corresponding to each of the position limiting slots 164. Please refer to FIG. 5a and FIG. 6b, two opposite walls of the positioning tower 16 are formed with a pair of position limiting slots 164 of the position limiting mechanism and a pair of guide rails 165 of the guide mechanism, and two opposite walls of the lock body 21 are oppositely formed with a pair of block tenons 212 sleeved in the pair of position limiting slots 164, and a pair of guide slots 211 sleeved in the pair of guide rails 165; wherein, each of the block tenons 212 has a downwardly-sloped inclined guide surface 212a to facilitate the block tenon 212 to be sleeved in the corresponding position limiting slot 164.

Moreover, a bottom surface of the lock body 21 is disposed with an elastic member 23, for example a spring, sleeved in the support rod 166 and located at a location corresponding to the support rod 166, and an accommodation hole 213 accommodating the elastic member 23 and the support rod 166; wherein, the elastic member 23 and the accommodation hole 213 are defined as a part of the elastic retracting mechanism.

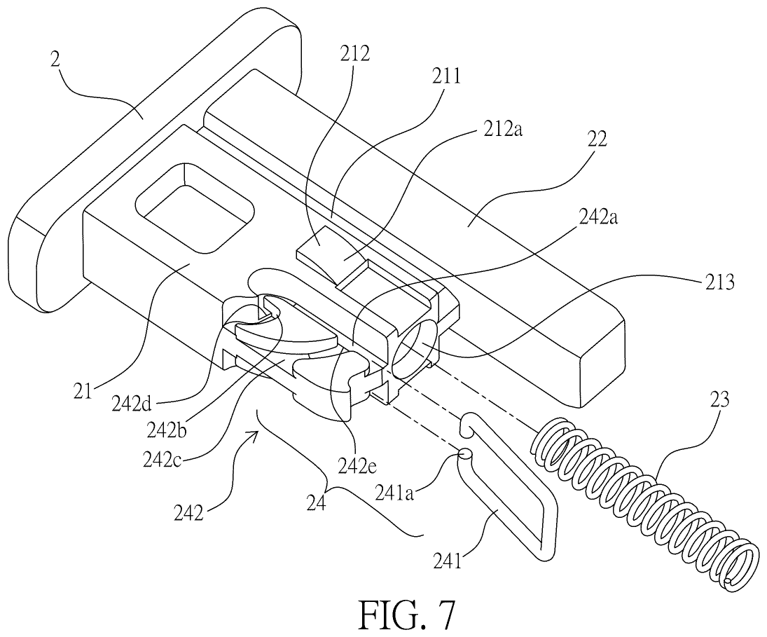

Furthermore, the lock body 21 is disposed with a positioning device 24 at a location corresponding to the hinge connecting member 167, the positioning device 24 includes a pair of U-shaped swing members 241 pivotally connected to the hinge connecting member 167, for example a pair of buckle slots 167b on a bottom surface of a pair of fasten sheets 167a, and at least one guide tenon 241a inwardly protruded at a top end of the swing member 241; and the lock body 21 has at least one rail mechanism 242 having a height differentiation and formed in a two-staged positioning status and located at a position corresponding to a lateral wall of the at least one guide tenon 241a, so that each of the guide tenons 241a is able to move and be positioned with respect to a preset stroke on the corresponding rail mechanism 242. Please refer to FIG. 7, there are a pair of rail mechanisms 242, and the two rail mechanisms 242 are symmetrically disposed on a front lateral wall and a rear lateral wall of the lock body 21, wherein each of the rail mechanisms 242 includes a linear slot 242a radially arranged, a heart-shaped concave slot 242b connected to a downstream end of the linear slot 242a, and an arc-shaped slot 242c connected to a downstream end of the heart-shaped concave slot 242b and an upstream end of the linear slot 242a, thereby configuring the rail mechanism 242 formed in a two-staged positioning status with a unidirectional stroke.

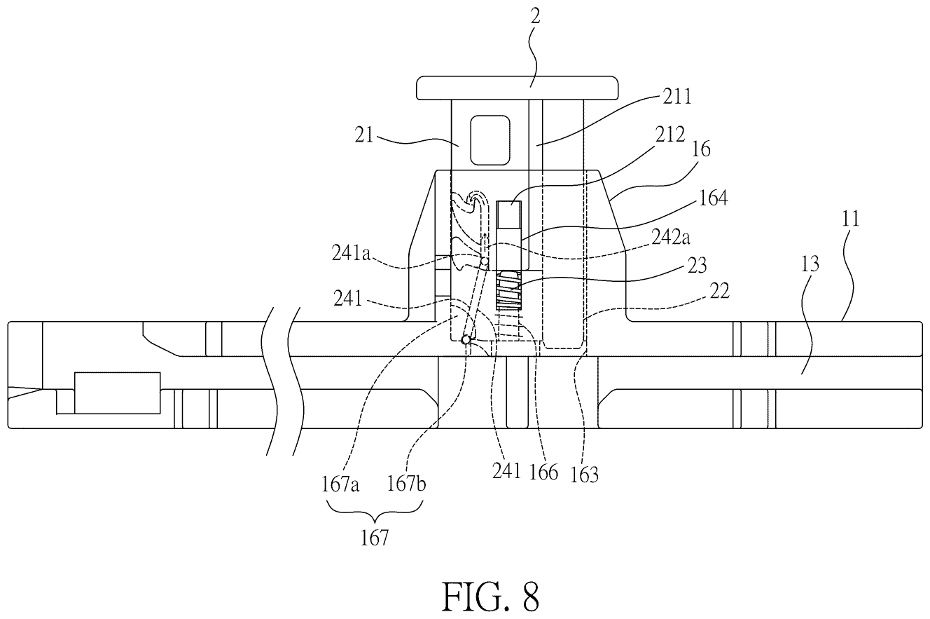

Please refer to FIG. 8, when the locking member 2 is not pressed, each of the block tenons 212 are abutted against a top end of the position limiting slot 164 through a stretching effect provided by the elastic member 23, each of the guide tenon 241a of the swing members 241 is located at an initial end of the corresponding linear slot 242a, thereby forming a first positioning status. At this moment, the first locking bolt 22 is accommodated in the accommodation slot 161.

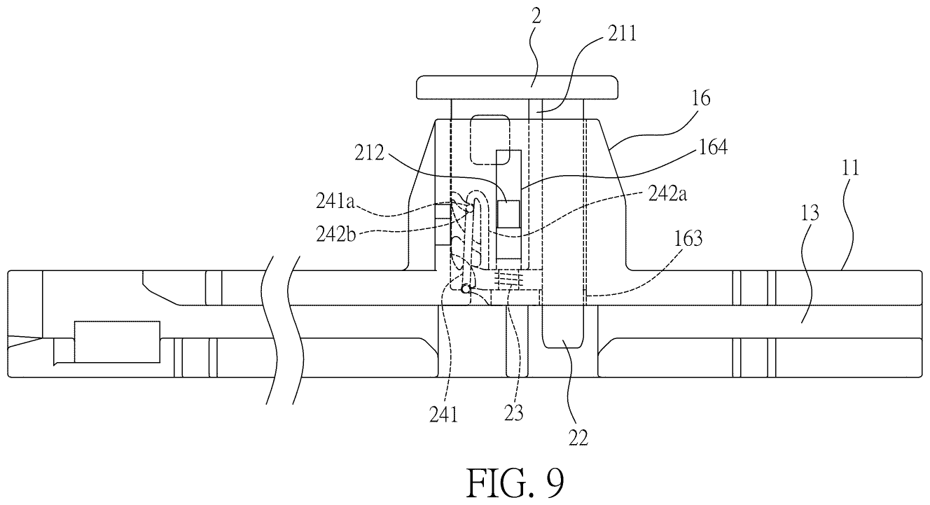

Please refer to FIG. 9, when the locking member 2 is pressed, each of the guide slots 211 and each of the block tenons 212 are downwardly moved along the corresponding guide rail 165 and the corresponding position limiting slot 164 through the elastic member 23 being compressed, each of the guide tenons 241a is upwardly moved along the linear slot 242s in a counterclockwise direction so as to enter the heart-shaped concave slot 242b, thereby forming a second positioning status. At this moment, the first locking bolt 22 protrudes out of the first bolt hole 163 and is disposed in the rail slot 13, thereby forming a locking status.

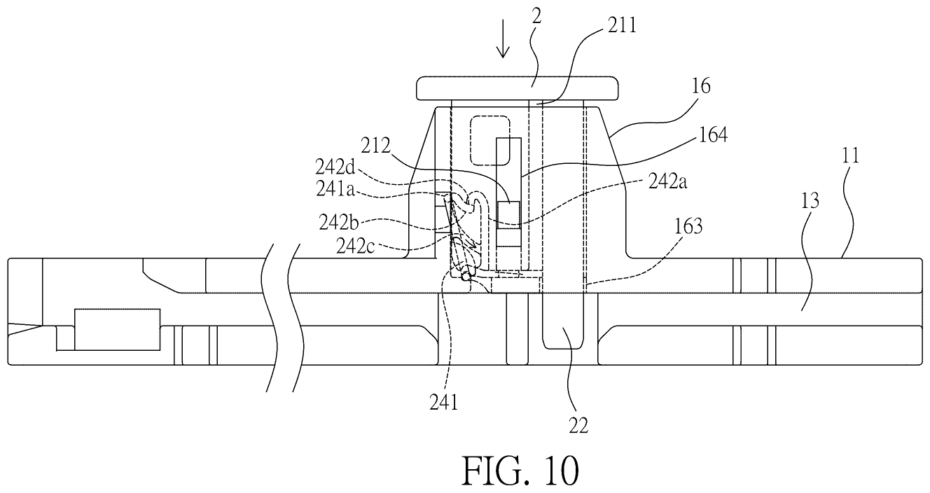

When the locking member 2 is desired to be unlocked, the locking member 2 is pressed again by the user as shown in FIG. 10; a connected location defined by the heart-shaped concave slot 242b and a linear slot 242a is formed with a first height differentiation segment 242d, in other words a terminal height of the linear slot 242a is greater than an initial height of the heart-shaped concave slot 242b, and each of the guide tenons 241a is released from the corresponding heart-shaped concave slot 242b and blocked by the adjacent first height differentiation segment 242d, so that each of the guide tenons 241a may only be moved towards the arc-shaped slot 242c in the counterclockwise direction.

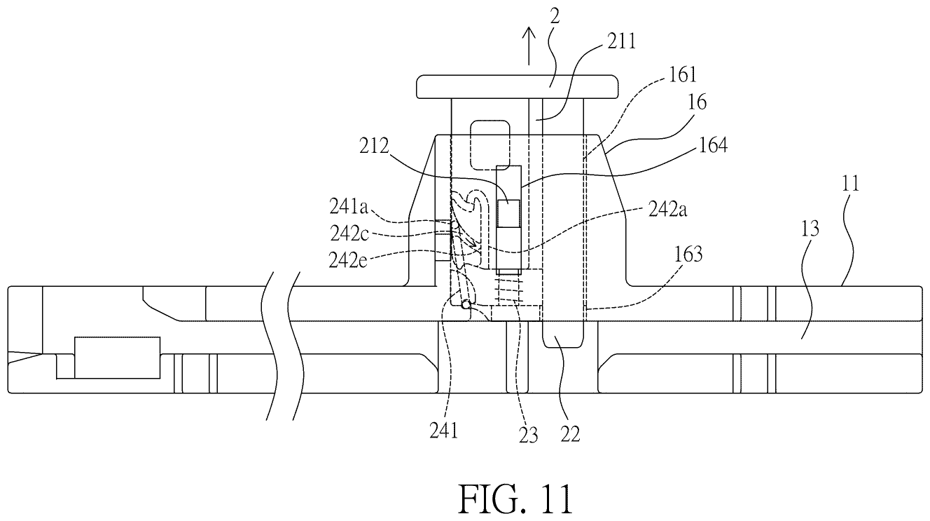

Please refer to FIG. 11, the locking member 2 is released by the user, the elastic member 23 is stretched, so that each of the guide slots 211 and each of the block tenons 212 are upwardly moved along the corresponding guide rail 165 and the corresponding position limiting slot 164, so that each of the guide tenons 241a is downwardly moved along the arc-shaped slot 242c in the counterclockwise direction till each of the guide tenons 241a passes a second height differentiation segment 242e defined at a connected location of the arc-shaped slot 242c and the linear slot 242a, and each of the block tenons 212 is abutted against a top end of the position limiting slot 164 through the locking member 2 being lifted and recovered, each of the block tenons 212 is abutted against the top end of the position limiting slot 164, and the guide tenon 241a of the swing member 241 is recovered to the initial end of the linear slot 242a, thereby forming the first positioning status; and the first locking bolt 22 is returned to be accommodated in the accommodation slot 161 as shown in FIG. 8, thereby forming an unlocking status.

According to the present invention, in the second height differentiation segment 242e, form the terminal height of the arc-shaped slot 242c is greater than a height defined at an upstream segment of the linear slot 242a, and each of the guide tenons 241a is blocked by the corresponding second height differentiation segment 242e when being moved in the counterclockwise direction, thus each of the guide tenons 241a may only be moved towards the linear slot 242a in the counterclockwise direction.

Please refer to FIG. 12 and FIG. 13, which disclose the first fixing rail 11 and the second fixing rail 12 of the sliding rail device 1 are arranged with an interval and fastened at two inner lateral sides in a board hole 105 preformed on the first board member 101, for example a motherboard, of the main frame 10, thereby forming the on-board status. The sliding rail device 1 allows a removeable unit 20, for example a network card, to be inserted, and the first board member 101 is disposed with a connector 102 located in the board hole 105 and a distal end of the sliding rail device 1. The removeable unit 20 includes a second board member 201, for example a circuit board, two sides thereof are oppositely protruded with a pair of sliding rails 202, and each of the sliding rails 202 has a locking hole 203; and an inner side of the second board member 201 is disposed with a connecting plug 204 at a location corresponding to the connector 102.

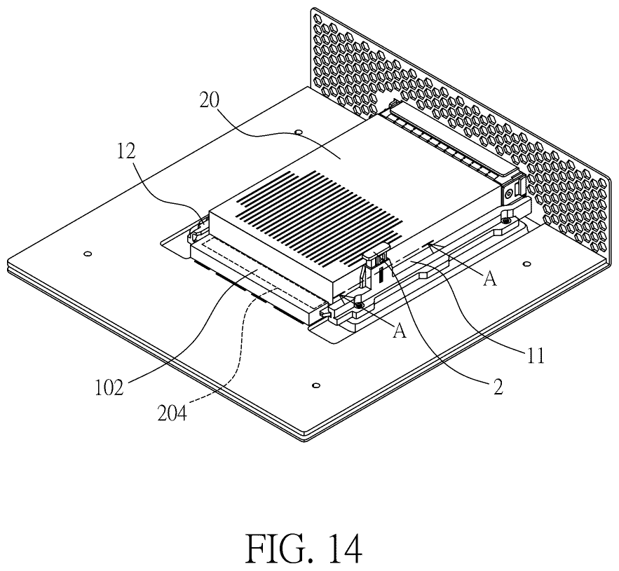

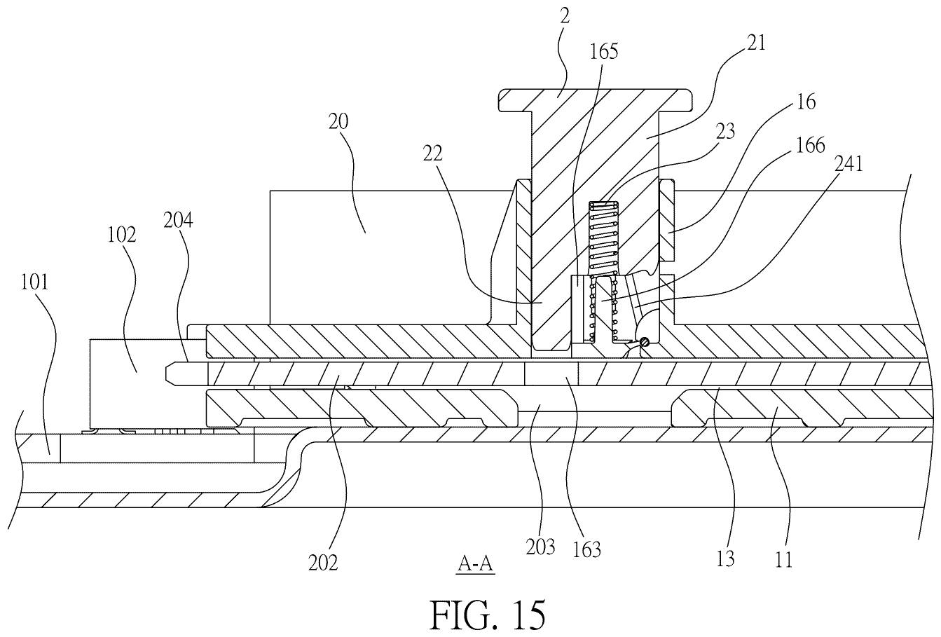

Please refer to FIG. 8, FIG. 14 and FIG. 15, a method of the removeable unit 20 being inserted in the main frame 10 is provided as follows. The pair of sliding rails 202 of the removable unit 20 are inserted in the pair of the rail slots 13 oppositely disposed on the first fixing rail 11 and the second fixing rail 12 by the user, so that each of the sliding rails 202 inwardly slides along the corresponding rail slot 13 till the connecting plug 204 is plugged in the connector 102 (as shown in FIG. 14), thereby forming an electric connection. The locking hole 203 of the removable unit 20 is located at a bottom end of the first bolt hole 163 (as shown in FIG. 15), the first locking bolt 22 is accommodated in the accommodation slot 161, thus the locking member 2 is in a non-pressed status. At this moment, each of the block tenons 212 of the locking member 2 as shown in FIG. 8 is abutted against the top end of the position limiting slot 164, and each of the guide tenons 241a of the swing member 241 is located at the initial end of the corresponding linear slot 242a, thereby forming the first positioning status in an unlocked condition.

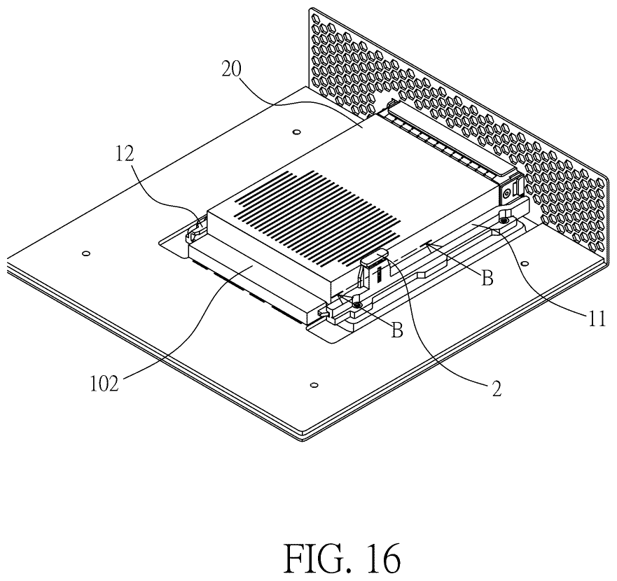

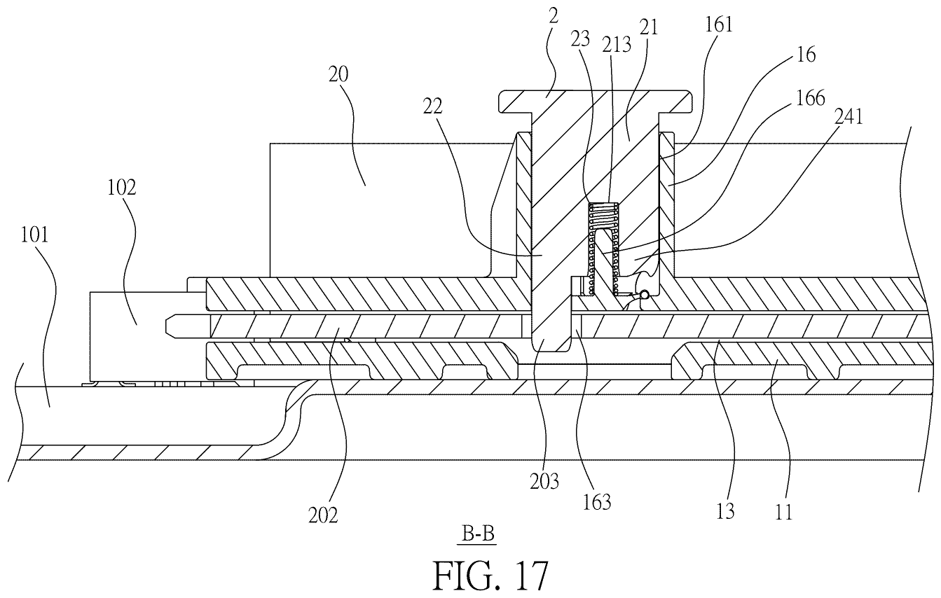

Please refer to FIG. 9, FIG. 16 and FIG. 17, a method of locking the removeable unit 20 in the main frame 10 is provided as follows. The locking member 2 is pressed by the user to make the elastic member 23 be compressed to store energy, and each of the guide slots 211 and each of the block tenons 212 are downwardly moved along the corresponding guide rail 165 and the corresponding position limiting slot 164, each of the guide tenons 241a is upwardly moved along the linear slot 242a in the counterclockwise direction and enters the heart-shaped concave slot 242b, thereby forming the second positioning status. At this moment, the first locking bolt 22 protrudes out of the first bolt hole 163 and is inserted in the locking hole 203 arranged in the rail slot 13, thereby forming a locking status to the removeable unit 20, and the removable unit 20 is prevented from being released from the main frame 10 due to being in a vibrating environment.

If the removeable unit 20 is desired to be unlocked and released from the main frame 10, the locking member 2 is pressed against to make the locking member 2 be in the non-pressed status as shown in FIG. 10 and FIG. 11, each of the guide tenons 241a is released from the corresponding heart-shaped concave slot 242b, each of the guide slots 211 and each of the block tenons 212 are upwardly moved along the corresponding guide rail 165 and the corresponding position limiting slot 164, and each of the guide tenons 241a is downwardly moved along the arc-shaped slot 242c along the counterclockwise direction till each of the guide tenons 241a passes the arc-shaped slot 242c to enter the linear slot 242a, and at this moment each of the block tenons 212 is abutted against the top end of the position limiting slot 164 through the locking member 2 being lifted and recovered, and the guide tenon 241a of the swing member 241 is recovered to the initial end of the linear slot 242a, thereby forming the first positioning status in the unlocked condition, and the first locking bolt 22 is returned to be accommodated in the accommodation slot 161 as shown in FIG. 8. At this moment, the removeable unit 20 can be released from the sliding rail device 1 of the main frame 10.

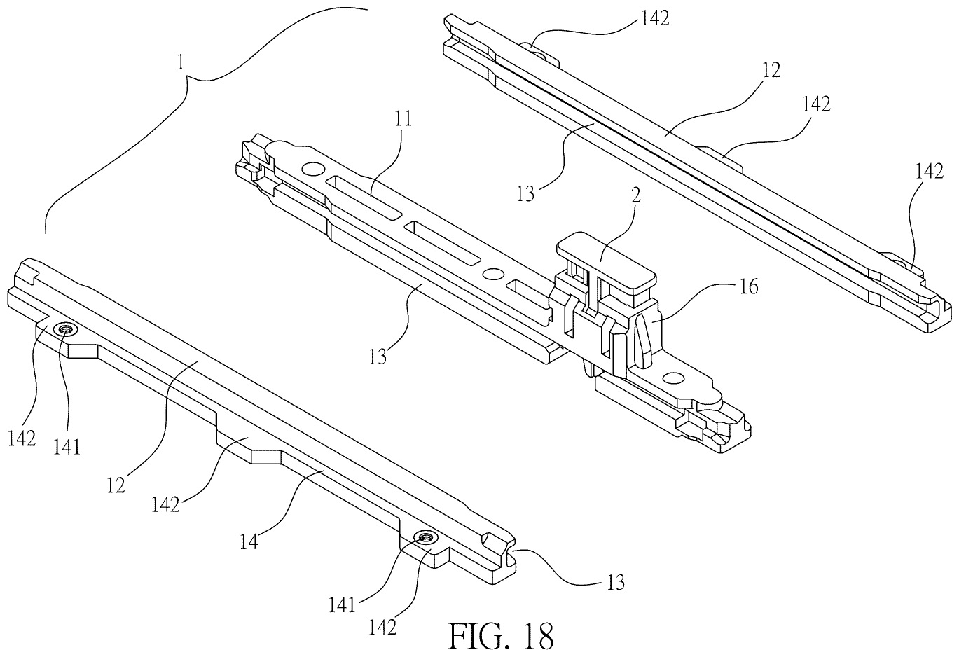

Please refer to FIG. 18, which disclose a second embodiment of the auxiliary sliding connection assembly provided by the present invention, the same codes (marks) shared by the second embodiment and the first embodiment are defined as the same components, because there are a lot of components shared by the second embodiment and the first embodiment, only the differences between the second embodiment and the first embodiment are provided as follows.

According to the second embodiment, the auxiliary sliding connection assembly is an insulation body integrally formed with a plastic material being processed with an injection molding means and includes a sliding rail device 1 and a locking member 2. The sliding rail device 1 includes a first fixing rail 11 arranged at the middle and a pair of second fixing rails 12 arranged with an interval and disposed two sides of the first fixing rail 11. Two lateral surfaces of the first fixing rail 11 and a lateral surface of each of the second fixing rails 12, which are opposite to each other, are axially formed with two pair of rail slots 13. Moreover, a bottom surface of the first fixing rail 11 and that of the second fixing rail 12 (not shown in figures) are respectively formed with at least one positioning tenon 132 so as to be easily mounted in the positioning hole 108 (as shown in FIG. 12) correspondingly formed on a first board member 101 of a main frame 10.

A bottom end defined at an outer lateral surface of the pair of second fixing rails 12 is radially formed with a lateral piece 14, respectively. The lateral piece 14 has at least one screw hole 141, each of the screw holes 141 allows a conventional screwing member, for example a screw, to pass so as to be screwed and connected to a penetrated hole preformed on the first board member 101. Wherein, the at least one screw hole 141 is selectively disposed in a plurality of protruding parts 142 radially protruded from the lateral piece 14, respectively. As shown in FIG. 18, there are two screw holes 141, which are disposed at a front portion and a rear portion of the protruding part 142, respectively. A bottom surface of the first fixing rail 11 is not only formed with the aforesaid positioning tenon 132, but also formed with at least one bottom connection hole 133 arranged with an interval relative to the positioning tenon 132.

A top surface of the first fixing rail 11 has a positioning tower 16 allowing the locking member 2 to be disposed, the positioning tower 16 has an accommodation slot 161, the accommodation slot 161 has an opening 162 and a first bolt hole 163 and a second bolt hole 163′ oppositely located at a top end and a bottom end thereof, and the first bolt hole 163 and the second bolt hole 163′ are in communication with the corresponding pair of rail slots 13.

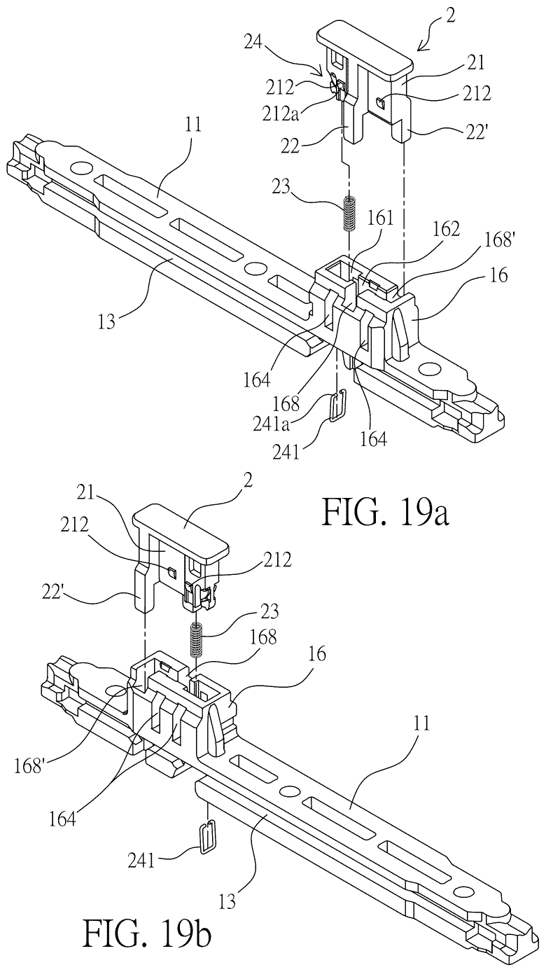

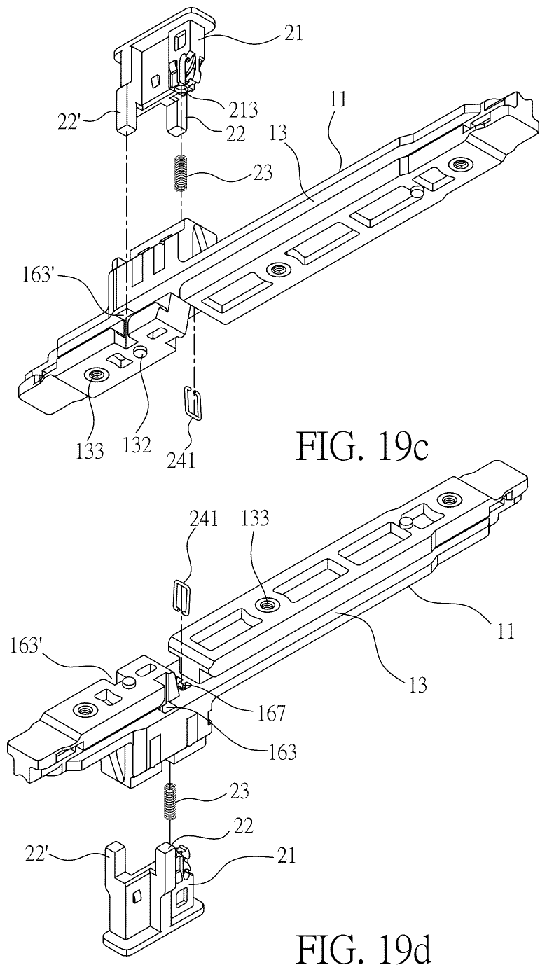

At least one lateral wall of the positioning tower 16 is radially formed with at least one position limiting slot 164 of a position limiting mechanism, two lateral walls of the positioning tower 16 are formed with a first guide slot 168 and a second guide slot 168′ of a guide mechanism; as shown from FIG. 19a to FIG. 19d, an inner lateral wall and an outer lateral wall of the positioning tower 16 are respectively formed with two of the position limiting slots 164, the first guide slot 168 communicating with the first bolt hole 163 and the second guide slot 168′ communicating with the second bolt hole 163′, the position limiting slots 164 are used to be combined with the locking member 2 and determine a radial moving stroke of the locking member 2, and the locking member 2 is prevented from being released from the opening 162 of the positioning tower 16. The first guide rail 168 and the second guide rail 168′ allow the locking member 2 to radially move in the positioning tower 16 in a stable and smooth manner.

Moreover, a middle segment defined at a bottom end of the positioning tower 16 is radially protruded with a support rod (shielded in the positioning tower 16 due to the projection angle) of an elastic retracting mechanism, and a corner thereof is disposed with a hinge connecting member 167 (as shown in FIG. 19d). As disclosed in the first embodiment, the hinge connecting member 167 includes at least one fasten sheet 167a, and a buckle slot 167b on a bottom surface of the fasten sheet 167a.

The locking member 2 includes a lock body 21, and two lateral walls thereof, for example an inner lateral wall and an outer lateral wall, are extended with a first locking bolt 22 and a second locking bolt 22′. Wherein, the first locking bolt 22 is disposed in via the opening 162 and sleeved in the first guide slot 168 to make the first locking bolt 22 radially move in the first bolt hole 163, the second locking bolt 22′ is disposed in via opening 162 and sleeved in the second guide slot 168′ to make the second locking bolt 22′ radially move in the second bolt hole 163′, and two lateral walls of the lock body 21 are respectively formed with a block tenon 212 of the position limiting mechanism at a location corresponding to each of the position limiting slots 164. Please refer from FIG. 19a to FIG. 19d, two opposite walls of the positioning tower 16 are respectively formed with the pair of position limiting slots 164 of the position limiting mechanism and the first guide slot 168 and the second guide slot 168′, which are staggeringly arranged, of the guide mechanism. Two opposite walls of the lock body 21 are oppositely formed with a pair of block tenons 212 sleeved in the pair of position limiting slots 164, and a pair of locking bolts 22, 22′ respectively sleeved in the first guide slot 168 and the second guide slot 168′; wherein each of the block tenons 212 has a downwardly-sloped inclined guide surface 212a to facilitate the block tenon 212 to be sleeved in the corresponding position limiting slot 164.

Moreover, a bottom surface of the lock body 21 is disposed with an elastic member 23, for example a spring, sleeving the support rod and arranged at a location corresponding to the support rod, and an accommodation hole 213 accommodating the elastic member 23 and the support rod; wherein the elastic member 23 and the accommodation hole 213 are defined as a part of the elastic retracting mechanism.

Furthermore, the lock body 21 is disposed with a positioning device 24 at a location corresponding to the hinge connecting member 167, the positioning device 24 includes a pair of U-shaped swing members 241 pivotally connected to the hinge connecting member 167, for example a pair of buckle slots 167b on a bottom surface of a pair of fasten sheets 167a, and at least one free end defined at a top end of the swing member 241 is inwardly protruded with a guide tenon 241a; and at least one rail mechanism 242 disposed corresponding to a lateral wall of the lock body 21. Please refer from FIG. 19a to FIG. 19d, there are a pair of rail mechanisms 242, and the two rail mechanisms 242 are symmetrically disposed on a front lateral wall and a rear lateral wall of the lock body 21, wherein the technical features of each of the rail mechanisms 242 are the same as the rail mechanism formed in the two-staged positioning status with the unidirectional stroke disclosed in the first embodiment, therefore no further illustration is provided.

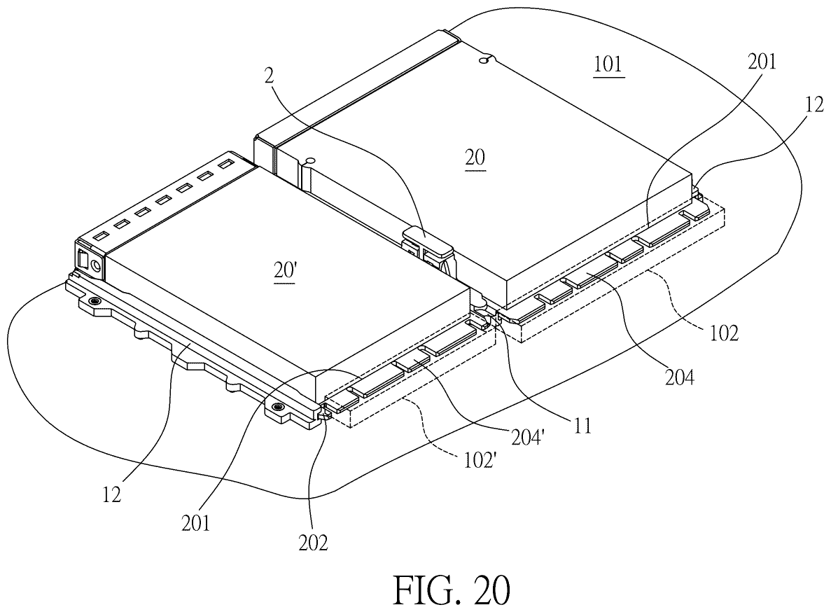

Please refer to FIG. 20, which discloses the first fixing rail 11 and the two second fixing rails 12 are arranged with an interval and fastened on the first board member 101, for example a motherboard, of the main frame 10, thereby forming an on-board status. The sliding rail device 1 allows a first removeable unit 20 and a second removeable unit 20′ having difference specifications, for example a network card, to be inserted, and the first board member 101 is respectively disposed with a first connector 102 and a second connector 102′ (marked in a dashed line) at a distal end of the sliding rail device 1. The first removeable unit 20 and the second removeable unit 20′ respecitvely have a second board member 201, for example a circuit board, and two sides of each of the second board members 201 are oppositely protruded with a pair of sliding rails 202, respectively; wherein the pair of sliding rails 202 of the first removeable unit 20 are respectively formed with a first locking hole (not shown in figures due to the projection angle), and the pair of sliding rails 202 of the second removeable unit 20′ are respectively formed with a second locking hole (not shown in figures due to the projection angle); inner sides of the second board members 201 are respectively disposed with a first connecting plug 204 and a second connecting plug 204′ at locations corresponding to the first connector 102 and the second connector 102′.

A method of the first removeable unit 20 and the second removeable unit 20′ being inserted in the main frame 10 of the auxiliary sliding connection assembly has been fully disclosed in FIG. 13 and FIG. 14, therefore no further illustration is provided. When the first removeable unit 20 and the second removeable unit 20′ are both inserted in the auxiliary sliding connection assembly and positioned, the locking member 2 is pressed by the user, the at least one guide tenon 241a of the swing member 241 is located in the rail mechanism 242 disposed corresponding the lateral wall of the lock body 21 to form the second positioning status, so that the first locking bolt 22 protrudes out of the first bolt hole 163 and is inserted in the first locking hole arranged in the rail slot 13, the second locking bolt 22′ protrudes out of the second bolt hole 163′ and is inserted in the second locking hole arranged in the rail slot 13, thereby simultaneously forming a locking status to the first removeable unit 20 and the second removeable unit 20′.

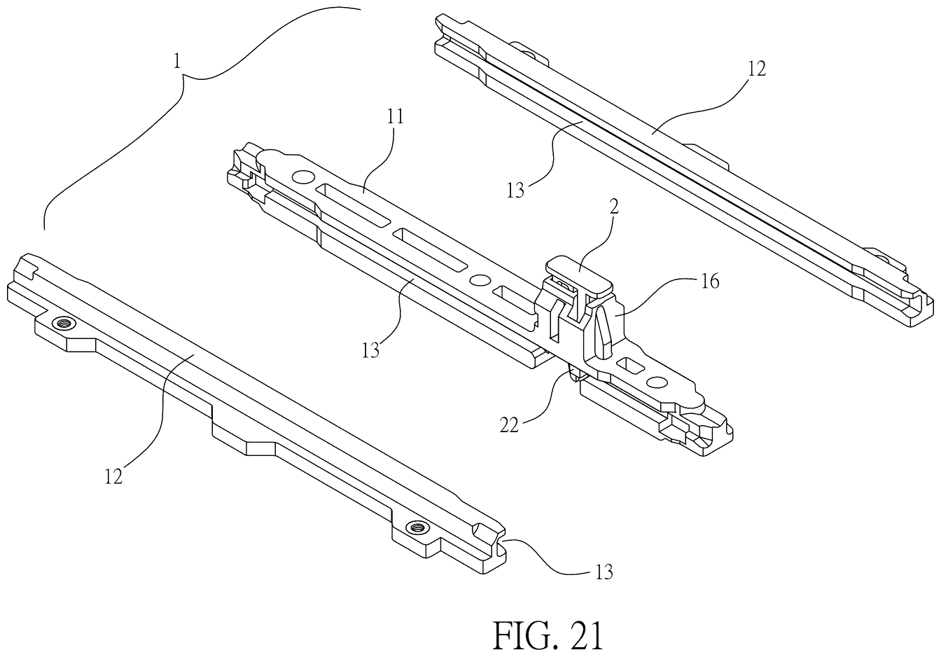

Please refer to FIG. 21, which disclose a third embodiment of the auxiliary sliding connection assembly provided by the present invention, the same codes (marks) shared by the third embodiment and the second embodiment are defined as the same components, because there are a lot of components shared by the second embodiment and the first embodiment, only the differences between the third embodiment and the second embodiment are provided as follows.

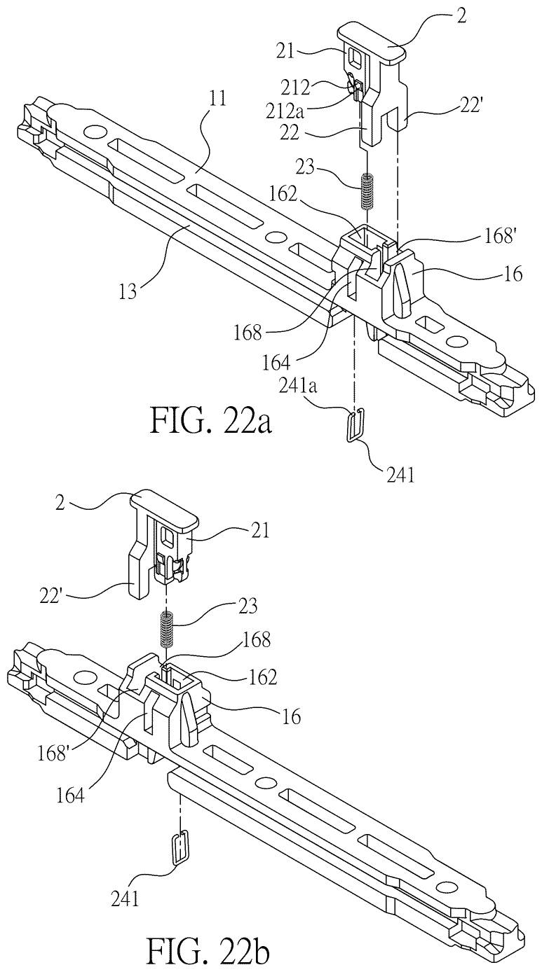

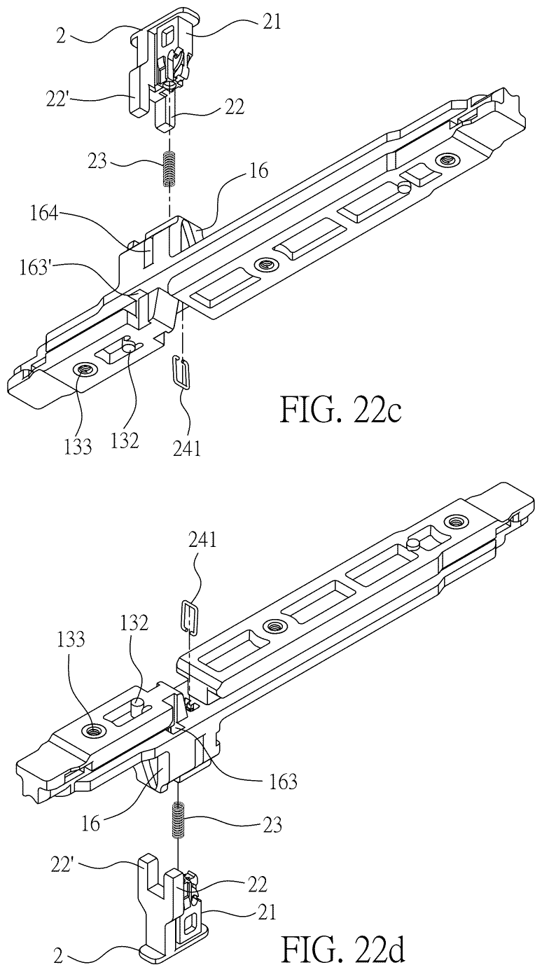

According to the third embodiment, the auxiliary sliding connection assembly is an insulation body integrally formed with a plastic material being processed with an injection molding means, and includes a sliding rail device 1 and a locking member 2. The sliding rail device 1 includes a first fixing rail 11 arranged at the middle and a pair of second fixing rails 12 disposed at two sides of the first fixing rail 11. The technical differences between the third embodiment and the second embodiment are as follows. Please refer from FIG. 22a to FIG. 22d, the inner wall and an outer wall of the positioning tower 16 are respectively formed with a position limiting slot 164 and a first guide slot 168 communicating with a first bolt hole 163 and the second guide slot 168′ communicating with the second bolt hole 163′, and the first guide slot 168 and the second guide slot 168′ are configured in a means of facing each other; and two lateral walls, for example an inner lateral wall and an outer lateral wall, of the lock body 21 of the locking member 2 are symmetrically protruded with a first locking bolt 22 and a second locking bolt 22′, respectively. The first locking bolt 22 is disposed in via the opening 162 and sleeved in the first guide slot 168 to make the first locking bolt 22 radially move in the first bolt hole 163, the second locking bolt 22′ is disposed in via the opening 162 and sleeved in the second guide slot 168′ to make the second locking bolt 22′ radially move in the second bolt hole 163′.

The advantage of the first locking bolt 22 and the second locking bolt 22′ of the locking member 2 being symmetrically disposed is that the first removeable unit 20 and the second removeable unit 20′ having the same specification can be adopted.

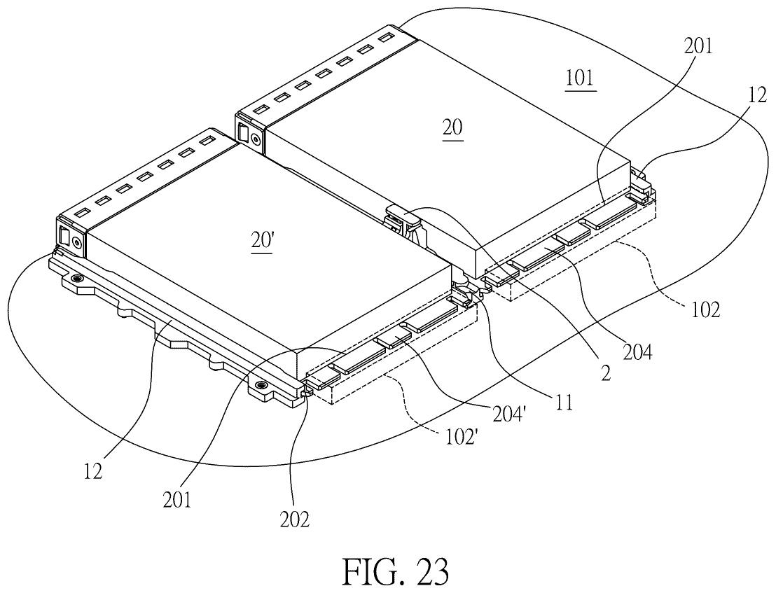

Please refer to FIG. 23, which discloses a method of the first removeable unit 20 and the second removeable unit 20′ having the same specification being inserted in the auxiliary sliding connection assembly of the main frame 10 which is the same as the method disclosed in FIG. 13 and FIG. 14, therefore no further illustration is provided. When the first removeable unit 20 and the second removeable unit 20′ are both inserted in the auxiliary sliding connection assembly and positioned, the locking member 2 is pressed by the user, the at least one guide tenon 241a of the swing member 241 is located in the rail mechanism 242 disposed corresponding to the lateral wall of the lock body 21 to form the second positioning status, so that the first locking bolt 22 protrudes out of the first bolt hole 163 and is inserted in the first locking hole arranged in the rail slot 13, the second locking bolt 22′ protrudes out of the second bolt hole 163′ and is inserted in the second locking hole arranged in the rail slot 13, thereby simultaneously forming a locking status to the first removeable unit 20 and the second removeable unit 20′.

Based on what has been disclosed above, advantages achieved by the present invention are as follows. The first fixing rail and the at least one second fixing rail of the auxiliary sliding connection assembly allow the first board member having different configurations to be formed with the on-board status and the in-board status relative to the fixing rails, the first fixing rail is disposed with the two-stage locking member, capable of manually locking and unlocking the locking hole, arranged at the location corresponding to the locking hole preformed on the second board member, so that the removeable unit, for example the network card, having the second board member, for example the circuit board, is able to generate the locking and positioning function to the main frame, for example the server, having the first board member, for example the motherboard, during the sliding process of the sliding rail device, thus the connector of the first board member and the connecting plug of the second board member are prevented from loosening or separating, thereby ensuring the stability of the electric connection. Moreover, the locking and the unlocking operation for the auxiliary sliding connection assembly can be done with only one hand, and the other hand of the user can hold the removeable unit for processing a removing and separating operation. Accordingly, the auxiliary sliding connection assembly provided by the present invention is novel and more practical in use compared to prior art.

While the invention has been described by way of example and in terms of preferred embodiments, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. An auxiliary sliding connection assembly, including:
a sliding rail device, including a first fixing rail and a second fixing rail arranged with an interval and disposed on a first board member, a lateral surface of the first fixing rail and a lateral surface of the second fixing rail, which are opposite to each other, are axially formed with a pair of rail slots for allowing a pair of sliding rails at two sides of a second board member to be disposed and slide thereon; wherein the first fixing rail has a positioning tower arranged at a location corresponding to a locking hole formed on the pair of sliding rails, the positioning tower has an accommodation slot, the accommodation slot has an opening and a first bolt hole oppositely located at a top end and a bottom end thereof, and the first bolt hole is in communication with one of the rail slots, the positioning tower further has a hinge connecting member disposed at a bottom end thereof; and
a locking member, disposed in the positioning tower and including a lock body extended with a first locking bolt at a bottom end thereof, the first locking bolt is able to radially protrude out of the first bolt hole, an elastic retracting mechanism is disposed at a bottom end of an adjacently connected surface defined by the lock body and the positioning tower, a position limiting mechanism is oppositely disposed on at least one lateral wall of the positioning tower and a lateral wall corresponding to the lock body, and the lock body has a positioning device at a location corresponding to the hinge connecting member, the positioning device includes a swing member pivotally connected to the hinge connecting member, at least one guide tenon is inwardly protruded on a top surface of the swing member; and the lock body has at least one rail mechanism having a height differentiation and formed in a two-staged positioning status and located at a position corresponding to a lateral wall of the at least one guide tenon;
when the locking member is pressed, the elastic retracting mechanism is compressed to store energy, the position limiting mechanism determines a radial moving limitation in which the locking member moves in the positioning tower; and the at least one guide tenon moves within a preset stroke on a corresponding said rail mechanism, so that the first locking bolt protrudes out of the first bolt hole and passes the locking hole in one of the rail slots, thereby forming a locking status; or the first locking bolt is released from the locking hole in one of the rail slots and retracted in the first bolt hole, thereby forming an unlocking status.

2. The auxiliary sliding connection assembly as claimed in claim 1, wherein a lateral piece is radially formed at a bottom end defined at another lateral surface of the first fixing rail and another lateral surface of the second fixing rail, the lateral piece has at least one screw hole; wherein each of the screw holes is allowed to pass so as to be screwed and connected to a penetrated hole correspondingly formed on the first board member; and the at least one screw hole is selectively disposed in a plurality of protruding parts radially protruded from the lateral piece, respectively.

3. The auxiliary sliding connection assembly as claimed in claim 1, further including a guide mechanism, the guide mechanism is oppositely disposed with at least one guide rail arranged on the at least one lateral wall of the positioning tower and the lateral wall corresponding to the lock body, and a guide slot sleeved in each of the guide rails, so that the locking member is able to radially move in the positioning tower in a stable and smooth manner.

4. The auxiliary sliding connection assembly as claimed in claim 1, wherein at least one positioning tenon is respectively protruded from a bottom surface of the first fixing rail and a bottom surface of the second fixing rail; wherein each of the positioning tenons is mounted in a positioning hole correspondingly formed on the first board member.

5. The auxiliary sliding connection assembly as claimed in claim 1, wherein the position limiting mechanism has at least one position limiting slot oppositely disposed on the at least one lateral wall of the positioning tower and the lateral wall corresponding to the lock body, and a block tenon sleeved in each of the position limiting slots to determine a radial moving stroke in which the locking member moves in the positioning tower, and the locking member is prevented from being released from the opening of the positioning tower.

6. The auxiliary sliding connection assembly as claimed in claim 5, wherein each of the block tenons has a downwardly-sloped inclined guide surface to facilitate the block tenon to be sleeved in the corresponding position limiting slot.

7. The auxiliary sliding connection assembly as claimed in claim 1, wherein the elastic retracting mechanism includes a support rod radially protruded from a middle segment defined at a bottom end of the positioning tower, a bottom surface of the lock body is disposed with an elastic member sleeving the support rod and arranged at a location corresponding to the support rod, and an accommodation hole accommodating the elastic member and the support rod.

8. The auxiliary sliding connection assembly as claimed in claim 1, wherein the hinge connecting member includes at least one fasten sheet, and a buckle slot allowing the swing sheet to be buckled and arranged on a bottom surface of one said fasten sheet.

9. The auxiliary sliding connection assembly as claimed in claim 1, wherein the rail mechanism includes a linear slot radially arranged, a heart-shaped concave slot connected to a downstream end of the linear slot, and an arc-shaped slot connected to a downstream end of the heart-shaped concave slot and an upstream end of the linear slot, wherein a first height differentiation segment is formed at a connected location defined by the heart-shaped concave slot and the linear slot, a second height differentiation segment is formed at a connected location defined by the arc-shaped slot and the linear slot, thereby configuring the rail mechanism formed in a two-staged positioning status with a unidirectional stroke.

10. An auxiliary sliding connection assembly, including:
a sliding rail device, including a first fixing rail disposed at a central segment of first board member and a pair of second fixing rails arranged with an interval and disposed at two sides of the first fixing rail, two lateral surfaces of the first fixing rail and a lateral surface of the pair of second fixing rails, which are opposite to each other, are axially formed with two pairs of rail slots, each of the two pairs of rail slots allow a pair of sliding rails at two sides of a second board member to be disposed and slide thereon;
wherein the first fixing rail has a positioning tower arranged at a location corresponding to a locking hole formed on the pair of sliding rails, the positioning tower has an accommodation slot, the accommodation slot has an opening and a first bolt hole and a second bolt hole oppositely located at a top end and a bottom end thereof, and the first bolt hole and the second bolt hole are in communication with one corresponding said rail slot, the positioning tower further has a hinge connecting member disposed at a bottom end thereof; and
a locking member, disposed in the positioning tower and including a lock body extended with a first locking bolt and a second locking bolt respectively protruded from two lateral walls thereof, the first locking bolt is able to radially protrude out of the first bolt hole and the second locking bolt is able to radially protrude out of the second bolt hole; an elastic retracting mechanism is disposed at a bottom end of an adjacently connected surface defined by the lock body and the positioning tower, a position limiting mechanism is oppositely disposed on at least one lateral wall of the positioning tower and a lateral wall corresponding to the lock body, and the lock body has a positioning device at a location corresponding to the hinge connecting member, the positioning device includes a swing member pivotally connected to the hinge connecting member, at least one guide tenon is inwardly protruded on a top surface of the swing member; and the lock body has at least one rail mechanism having a height differentiation and formed in a two-staged positioning status and located at a position corresponding to a lateral wall of the at least one guide tenon;
when the locking member is pressed, the elastic retracting mechanism is compressed to store energy, the position limiting mechanism determines a radial moving limitation in which the locking member moves in the positioning tower; and the at least one guide tenon moves within a preset stroke on one corresponding said rail mechanism, so that the first locking bolt and the second locking bolt respectively protrude out of the first bolt hole and the second bolt hole and respectively pass the locking hole in one of the rail slots, thereby forming a locking status; or the first locking bolt and the second locking bolt are respectively released from the locking hole in one of the rail slots and retracted in the first bolt hole and the second bolt hole, thereby forming an unlocking status.

11. The auxiliary sliding connection assembly as claimed in claim 10, wherein at least one bottom connection hole arranged with an interval is formed on a bottom surface of the first fixing rail, a lateral piece is radially formed at a bottom end defined on another lateral surface of each said second fixing rail and arranged opposite to the first fixing rail, the lateral piece has at least one screw hole; wherein each of the screw holes is allowed to pass so as to be screwed and connected to a penetrated hole correspondingly formed on the first board member; and the at least one screw hole is selectively disposed in a plurality of protruding parts radially protruded from the lateral piece, respectively.

12. The auxiliary sliding connection assembly as claimed in claim 10, further including a guide mechanism, the guide mechanism is respectively disposed with a first guide slot communicating with the first bolt hole and a second guide slot communicating with the second bolt hole and arranged on two lateral walls of the positioning tower; wherein the first locking bolt is sleeved in the first guide slot so as to radially move in the first bolt hole, and the second locking bolt is sleeved in the second guide slot so as to radially move in the second bolt hole, so that the locking member is able to radially move in the positioning tower in a stable and smooth manner.

13. The auxiliary sliding connection assembly as claimed in claim 12, wherein the first locking bolt, the first guide slot and the first bolt hole are staggeringly arranged relative to the second locking bolt, the second guide slot and the second bolt hole.

14. The auxiliary sliding connection assembly as claimed in claim 12, wherein the first locking bolt, the first guide slot and the first bolt hole are oppositely and symmetrically arranged relative to the second locking bolt, the second guide slot and the second bolt hole.

15. The auxiliary sliding connection assembly as claimed in claim 10, wherein at least one positioning tenon is respectively protruded from a bottom surface of the first fixing rail and a bottom surface of the second fixing rail; wherein each of the positioning tenons is mounted in a positioning hole correspondingly formed on the first board member.

16. The auxiliary sliding connection assembly as claimed in claim 10, wherein the position limiting mechanism has at least one position limiting slot oppositely disposed on the at least one lateral wall of the positioning tower and the lateral wall corresponding to the lock body, and a block tenon sleeved in each of the position limiting slots to determine a radial moving stroke in which the locking member moves in the positioning tower, and the locking member is prevented from being released from the opening of the positioning tower.

17. The auxiliary sliding connection assembly as claimed in claim 16, wherein each of the block tenons has a downwardly-sloped inclined guide surface to facilitate the block tenon to be sleeved in the corresponding position limiting slot.

18. The auxiliary sliding connection assembly as claimed in claim 10, wherein the elastic retracting mechanism includes a support rod radially protruded from a middle segment defined at a bottom end of the positioning tower, a bottom surface of the lock body is disposed with an elastic member sleeving the support rod and arranged at a location corresponding to the support rod, and an accommodation hole accommodating the elastic member and the support rod.

19. The auxiliary sliding connection assembly as claimed in claim 10, wherein the hinge connecting member includes at least one fasten sheet, and a buckle slot allowing the swing sheet to be buckled and arranged on a bottom surface of one said fasten sheet.

20. The auxiliary sliding connection assembly as claimed in claim 10, wherein the rail mechanism includes a linear slot radially arranged, a heart-shaped concave slot connected to a downstream end of the linear slot, and an arc-shaped slot connected to a downstream end of the heart-shaped concave slot and an upstream end of the linear slot, wherein a first height differentiation segment is formed at a connected location defined by the heart-shaped concave slot and the linear slot, a second height differentiation segment is formed at a connected location defined by the arc-shaped slot and the linear slot, thereby configuring the rail mechanism formed in a two-staged positioning status with a unidirectional stroke.
